(19) United States
(12) Patent Application Publication
(10) Pub. No.: US 2016/0172436 A1
(43) Pub. Date: Jun. 16, 2016

(54) SEMICONDUCTOR DEVICE, TERMINATION STRUCTURE AND METHOD OF FORMING THE SAME

(71) Applicant: Episil Technologies Inc., Hsinchu City (TW)

(72) Inventors: Geng-Tai Ho, Hsinchu City (TW); Shih-Kuei Ma, Hsinchu City (TW); Tien-Chun Lee, Hsinchu City (TW); Meng-Hung Chen, Hsinchu City (TW); Hsiao-Chia Wu, Hsinchu City (TW)

(21) Appl. No.: 14/749,655

(22) Filed: Jun. 25, 2015

(30) Foreign Application Priority Data
Dec. 12, 2014 (TW) 103143498

(51) Int. Cl. H01L 29/06; H01L 21/266; H01L 23/58; H01L 29/16; H01L 29/20; H01L 21/762; H01L 21/324

(52) U.S. Cl. CPC H01L 29/0615; H01L 29/0649; H01L 21/762; H01L 21/266; H01L 21/324; H01L 29/1608; H01L 29/2003; H01L 23/585

(57) ABSTRACT

Provided is a termination structure including a substrate of a first conductivity type, an epitaxial layer of the first conductivity type, a single bulk isolation structure and a bulk doped region of a second conductivity type. The epitaxial layer is disposed on the substrate. The single bulk isolation structure is disposed on the epitaxial layer. The bulk doped region is disposed in the epitaxial layer below the single bulk isolation structure, wherein the doping depth of the bulk doped region has a gradient distribution. A method of forming a termination structure and a semiconductor device having the termination structure are also provided.

### CROSS REFERENCE TO RELATED APPLICATION

This application claims the priority benefit of Taiwan application serial no. 103143498, filed on Dec. 12, 2014. The entirety of the above-mentioned patent application is hereby incorporated by reference herein and made a part of specification.

### BACKGROUND OF THE INVENTION

1. Field of Invention

The present invention relates to a semiconductor technology, and more particularly to a termination structure and a method of forming the same and a semiconductor device including the termination structure.

2. Description of Related Art

In recent years, high-voltage MOS devices have been widely used in all types of power integrated circuits or smart power integrated circuits. In order to enhance the performance of a device, the operation of a high-voltage MOS device requires a high breakdown voltage and a low on-state resistance (Ron).

The design of a termination structure plays a very important role in improving the breakdown voltage of a semiconductor device. As the level of integration of semiconductor devices is getting increased, the dimension of the same is getting reduced. Therefore, how to maintain or even improve the original breakdown voltage with decreasing the device dimension has become an important topic in the industry.

### SUMMARY OF THE INVENTION

Accordingly, the present invention provides a termination structure and a method of forming the same and a semiconductor device including the termination structure, in which a single bulk isolation structure is disposed on an epitaxial layer in a termination area, and the profile of the doped region below the single bulk isolation structure can be effectively controlled by the method herein described. Therefore, the breakdown voltage of the device can be easily improved.

The present invention provides a termination structure including a substrate of a first conductivity type, an epitaxial layer of the first conductivity type, a single bulk isolation structure and a bulk doped region of a second conductivity type. The epitaxial layer is disposed on the substrate. The single bulk isolation structure, is disposed on the epitaxial layer. The bulk doped region is disposed in the epitaxial layer below the single bulk isolation structure, wherein a doping depth of the bulk doped region has a graded distribution.

According to an embodiment of the present invention, the doping depth of the bulk doped region is gradually increased toward an active area.

According to an embodiment of the present invention, the single bulk isolation structure has a thickness of about 100 angstroms to 10,000 angstroms.

According to an embodiment of the present invention, the substrate includes silicon, silicon carbide or gallium nitride.

According to an embodiment of the present invention, the single bulk isolation structure is a field oxide layer.

According to an embodiment of the present invention, the first conductivity type is N-type and the second conductivity type is P-type; or the first conductivity type is P-type and the second conductivity type is N-type.

The present invention further provides a method of forming a termination structure. An epitaxial layer of a first conductivity type is formed on a substrate of the first conductivity type. A single bulk isolation structure is formed on the epitaxial layer. A photoresist layer is formed on the single bulk isolation structure, wherein the photoresist layer has a plurality of openings with different widths. An ion implantation process is performed by using the photoresist layer as a mask, so as to form a plurality of doped regions of a second conductivity type in the epitaxial layer below the single bulk isolation structure, wherein doping depths of the doped regions have a graded distribution.

According to an embodiment of the present invention, the doped regions are separate from each other, an i-th doped region is more away from the active area than an (i+1)-th doped region, a doping depth of the i-th doped region is less than a doping depth of the (i+1)-th doped region, and i is a positive integer.

According to an embodiment of the present invention, the method further includes performing an annealing process, so that the doped regions are connected to one another to form a bulk doped region.

According to an embodiment of the present invention, the ion implantation process has a doping energy of about 30 KeV to 1,000 KeV and a doping dose of about 1×10¹²/cm² to 100×10¹²/cm².

According to an embodiment of the present invention, the widths of the openings in the photoresist layer are gradually increased toward the active area.

According to an embodiment of the present invention, the single bulk isolation structure has a thickness of about 100 angstroms to 10,000 angstroms.

According to an embodiment of the present invention, the single bulk isolation structure is a field oxide layer.

According to an embodiment of the present invention, the first conductivity type is N-type and the second conductivity type is P-type; or the first conductivity type is P-type and the second conductivity type is N-type.

The present invention also provides a semiconductor device including a substrate of a first conductivity type, an epitaxial layer of the first conductivity type, a single bulk isolation structure and a bulk doped region of a second conductivity type. The substrate has a first area and a second area. The epitaxial layer is disposed on the substrate. The single bulk isolation structure is disposed on the epitaxial layer in the first area. The bulk doped region is disposed in the epitaxial layer below the single bulk isolation structure, wherein a doping depth of the bulk doped region is gradually decreased toward the second area.

According to an embodiment of the present invention, the single bulk isolation structure has a thickness of about 100 angstroms to 10,000 angstroms.

According to an embodiment of the present invention, the substrate includes silicon, silicon carbide or gallium nitride.

According to an embodiment of the present invention, the single bulk isolation structure is a field oxide layer.

According to an embodiment of the present invention, the substrate further includes a third area, and the first area is located between the second area and the third area.

According to an embodiment of the present invention, the first area is a termination area, the second area is a seal ring area, and the third area is an active area.

In view of the above, in the method of the invention, a photoresist layer serves as a mask, and ions penetrate through a single bulk isolation structure and into an epitaxial layer to create an ion distribution with gradually changed doping depth. Since the opening sizes of the photoresist layer can be precisely defined, the process window can be widened and the doping profile can be easily controlled, and thus, the breakdown voltage of the device can be significantly improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic cross-sectional views of a method of forming a semiconductor device according to an embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

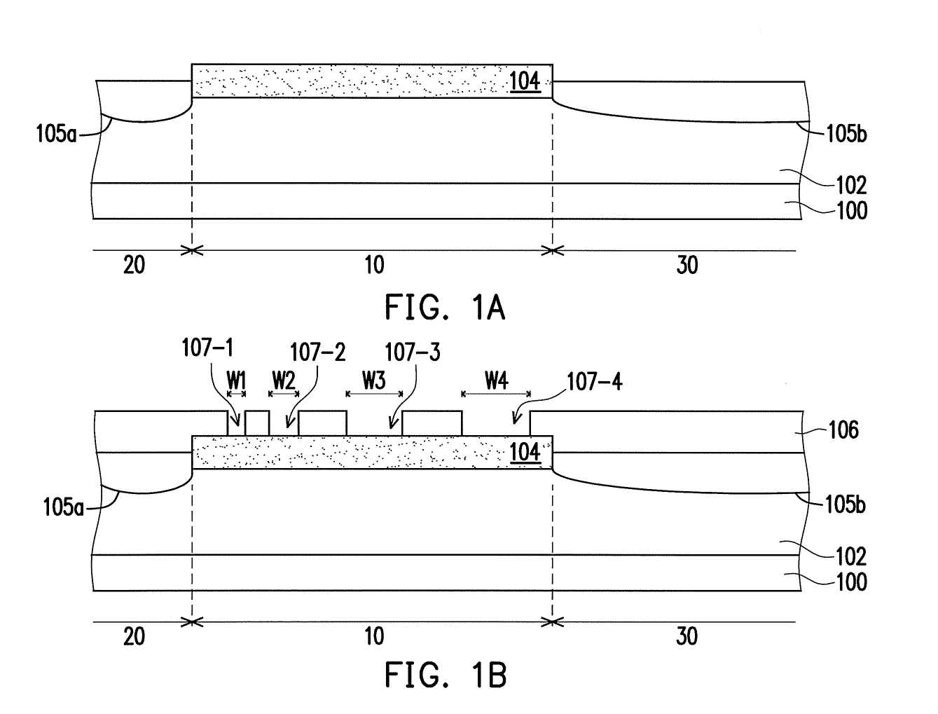

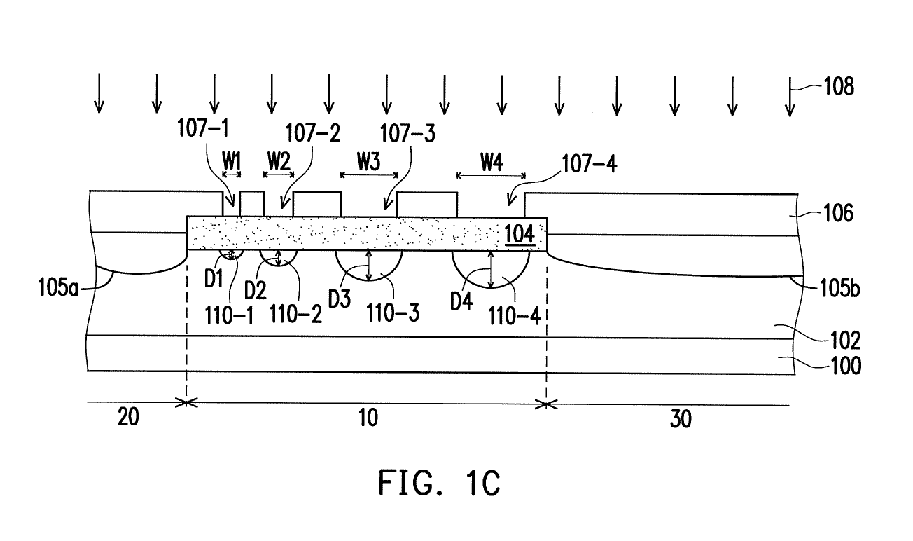

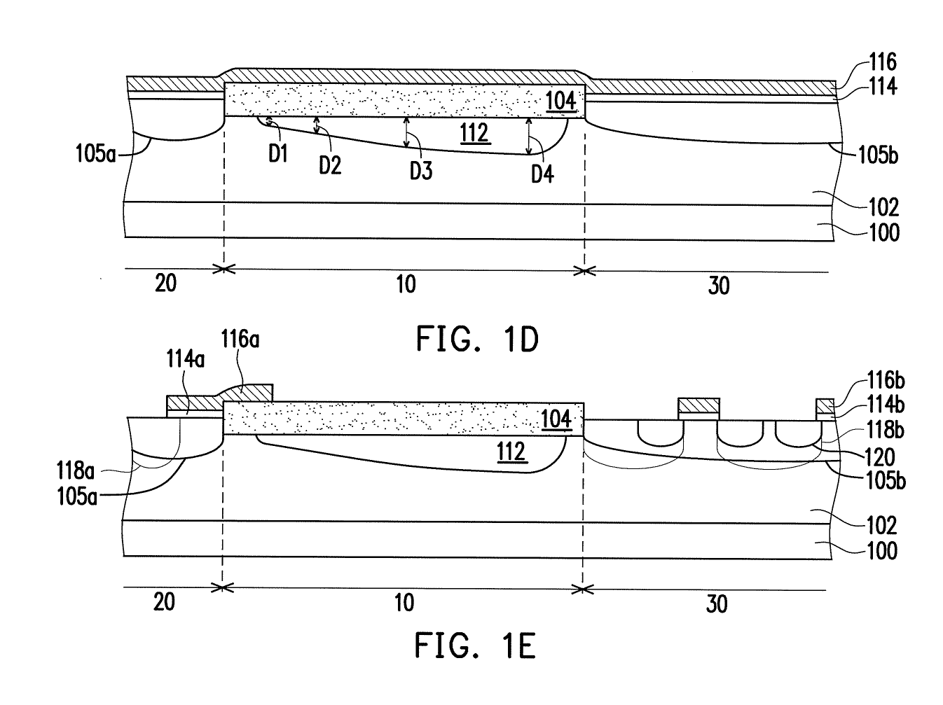

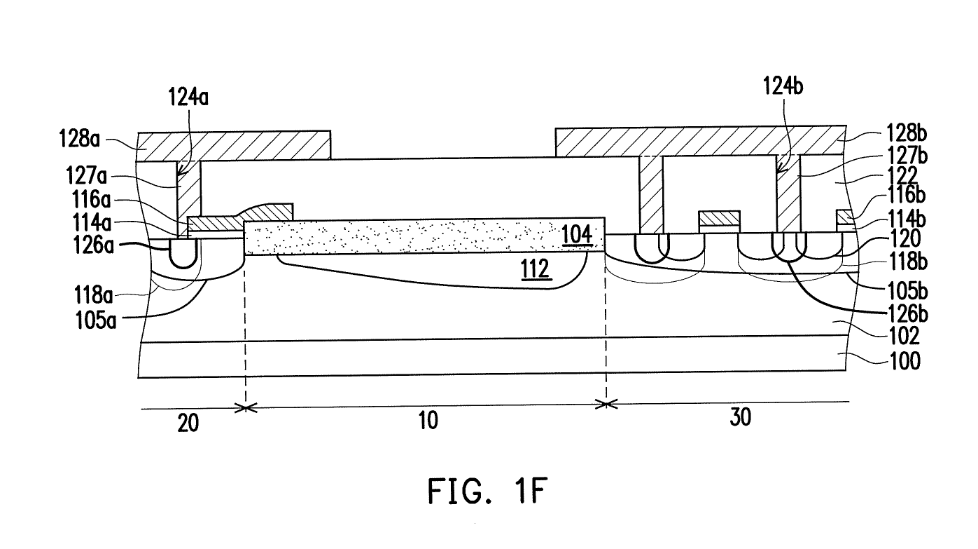

FIG. 1A to FIG. 1F are schematic cross-sectional views of a method of forming a semiconductor device according to an embodiment of the present invention.

Referring to FIG. 1A, an epitaxial layer 102 of a first conductivity type is formed on a substrate 100 of the first conductivity type. The substrate 100 can be an N-type heavily doped semiconductor substrate, serving as a drain region of the device. The substrate 100 includes silicon, silicon carbide or gallium nitride. The epitaxial layer 102 can be an N-type lightly doped epitaxial layer, and the forming method thereof includes performing a selective epitaxy growth (SEG) process. Besides, the substrate 100 has a first area 10, a second area 20 and a third area 30. The first area 10 is located between the second area 20 and the third area 30. In an embodiment, the first area 10 can be a termination area, the second area 20 can be a seal ring area, and the third area 30 can be an active area, but the present invention is not limited thereto. The device in the active area includes a lateral diffused metal-oxide semiconductor (LDMOS) device, a vertical diffused metal-oxide semiconductor (VDMOS) device, an insulated gate bipolar transistor (IGBT) device, a diode device, a bipolar junction transistor (BJT) device, a junction field effect transistor (JFET) device, another semiconductor device or a combination thereof. The following embodiment in which a VDMOS device is configured in the active area is provided for illustration purposes, and is not construed as limiting the present invention.

Thereafter, a single bulk isolation structure 104 is formed on the epitaxial layer 102 in the first area 10. More specifically, the first area 10 merely has a single isolation structure therein, and this isolation structure is a bulk structure without openings or a single-ring structure from a top view. The single bulk isolation structure 104 includes silicon oxide and has a thickness of about 100 angstroms to 10,000 angstroms, e.g. about 1,000 angstroms to 9,000 angstroms, 2,000 angstroms to 8,000 angstroms, 3,000 angstroms to 7,000 angstroms, 4,000 angstroms to 6,000 angstroms, or 5,000 angstroms to 5,500 angstroms. In an embodiment, the single bulk isolation structure 104 includes a field oxide layer. The method of forming the single bulk isolation structure 104 includes forming a mask layer (not shown) on the epitaxial layer 102, and the mask layer has an opening exposing a portion of the epitaxial layer 102. Thereafter, an oxidation process is conducted to grow a field oxide layer in the opening. The mask layer is then removed. In such manner, the surface of the epitaxial layer 102 in the first area 10 is lower than that in the second area 20 or in the third area 30.

Afterwards, a blanket ion implantation process is optionally performed by using the single bulk isolation structure 104 as a mask, so as to form doped regions 105a and 105b of a second conductivity type in the epitaxial layer 102 respectively in the second area 20 and in the third area 30. The doped regions 105a and 105b can be P-type doped regions. In an embodiment, the doped regions 105a and 105b can serve as JFET doped regions for reducing the on-state resistance below the device gate.

Referring to FIG. 1B, a photoresist layer 106 is formed on the single bulk isolation structure 104. The photoresist layer 106 has a plurality of openings 107-1, 107-2, 107-3 and 107-4 with different widths. In an embodiment, the widths W1, W2, W3 and W4 of the openings 107-1, 107-2, 107-3 and 107-4 in the photoresist layer 106 are gradually increased toward the third area 30 (e.g. active area) while gradually decreased toward the second area 20 (e.g. seal ring area). More specifically, the width W1 of the opening 107-1 is less than the width W2 of the opening 107-2, the width W2 of the opening 107-2 is less than the width W3 of the opening 107-3, and the width W3 of the opening 107-3 is less than the width W4 of the opening 107-4. In this embodiment, the photoresist layer 106 has four openings, but the present invention is not limited thereto. Upon the process requirements, the photoresist layer 106 can have three or more than four openings.

Referring to FIG. 1C, an ion implantation process 108 is performed by using the photoresist layer 106 as a mask, so as to form a plurality of doped regions 110-1, 110-2, 110-3 and 110-4 of the second conductivity type in the epitaxial layer 102 below the single bulk isolation structure 104. The doped regions 110-1, 110-2, 110-3 and 110-4 can be P-type doped regions. By controlling the doping energy and doping dose of the ion implantation process 108, the dopant penetrates through the openings of the photoresist layer 106 and the underlying single bulk isolation structure 104, and is implanted into the epitaxial layer 102 below the single bulk isolation structure 104. In an embodiment, the ion implantation process has a doping energy of about 30 KeV to 1,000 KeV and a doping dose of about 1×10¹²/cm² to 100×10¹²/cm². In this embodiment, the openings in the photoresist layer 106 are gradually varied, so the doping depths of the doped regions 110-1, 110-2, 110-3 and 110-4 are gradually changed. In an embodiment, the doping depths D1, D2, D3 and D4 of the doped regions 110-1, 110-2, 110-3 and 110-4 are gradually increased toward the third area 30 (e.g. active area) while gradually decreased toward the second area 20 (e.g. seal ring area). More specifically, the doped regions 110-1, 110-2, 110-3 and 110-4 are separate from each other, an i-th doped region is more away from the active area than an (i+1)-th doped region, the doping depth of the i-th doped region is less than that of the (i+1)-th doped region, and i is a positive integer. In other words, the doping depth D1 of the doped region 110-1 is less than the doping depth D2 of the doped region 110-2, the doping depth D2 of the doped region 110-2 is less than the doping depth D3 of the doped region 110-3, and the doping depth D3 of the doped region 110-3 is less than the doping depth D4 of the doped region 110-4. The photoresist layer 106 is then removed.

Referring to FIG. 1D, an annealing process is performed, so that the doped regions 110-1, 110-2, 110-3 and 110-4 are connected to one another to form a bulk doped region 112. The bulk doped region 112 and epitaxial layer 102 have a substantially smooth interface therebetween. The bulk doped region 112 can serve as a variation of lateral doping (VLD) region, for alleviating the PN junction punch trough caused by the junction curvature effect and thereby effectively improving the breakdown voltage. In an embodiment, the annealing process can be an oxidation process, so an insulating material layer 114 can be simultaneously formed on the epitaxial layer 102 in the second area 20 and in the third area 30. In other words, without an additional annealing process, the oxidation process for forming the insulating material layer 114 enables the doped regions 110-1, 110-2, 110-3 and 110-4 to connect to each other.

As shown in FIG. 1D, the doping depth of the bulk doped region 112 has a graded distribution, and the doping depths D1-D4 at positions along a horizontal direction are gradually increased toward the third area 30 (e.g. active area) while gradually decreased toward the second area 20 (e.g. seal ring area). The termination structure of the invention in the first area 10 is thus completed.

It is noted that, the method of the invention is relatively competitive since the opening sizes of the photoresist layer and therefore the profile of the formed doped regions can be effectively controlled with the method herein described. In the conventional method, a field oxide layer with openings is used as a mask, but it is difficult to control the opening sizes of the field oxide layer with an etching process. For example, a wet etching may laterally etch so the opening sizes are deviated from targets, and a dry etching may have polymer residues. However, in the present invention, a photoresist layer is used as a VLD mask, and ions then penetrate through the single bulk field oxide layer and into the epitaxial layer to create a VLD ion distribution. The opening sizes of the photoresist layer can be precisely defined, so a wider process window can be provided for mass production.

The termination structure of the invention in the first area 10 is illustrated with reference to FIG. 1D. In the termination structure of the invention, an epitaxial layer 102 is disposed on a substrate 100, a single bulk isolation structure 104 is disposed on the epitaxial layer 102, and a bulk doped region 112 is disposed in the epitaxial layer 102 below the single bulk isolation structure 104. In an embodiment, the epitaxial layer 102 has a conductivity type the same with that of the substrate 100 but different from that of the bulk doped region 112. The doping depth of the bulk doped region 112 has a graded distribution. More specifically, the doping depth of the bulk doped region 112 is gradually increased toward the third area 30 (e.g. active area).

The devices in the second and third areas 20 and 30 are then fabricated. Continue referring to FIG. 1D, a conductive material layer 116 is formed on the substrate 100 in the first, second and third areas 10, 20 and 30. The conductive material layer 116 includes doped polysilicon, and the forming method thereof includes performing a chemical vapour deposition (CVD) process.

Referring to FIG. 1E, the insulating material layer 114 and the conductive material layer 116 are patterned, so as to form an insulating layer 114a and a conductive layer 116a in the second area 20 and form an insulating layer 114b and a conductive layer 116b in the third area 30. In an embodiment, the conductive layer 116a further extends onto a portion of the single bulk isolation structure 104.

Thereafter, a blanket ion implantation process is performed by using the single bulk isolation structure 104 and the conductive layer 116a and 116b as a mask, so as to form doped regions 118a and 118b of the second conductivity type in the epitaxial layer 102 respectively in the second area 20 and in the third area 30. The doped regions 118a and 118b can serve as P-type body (PB) doped regions. In an embodiment, since the bulk doped region 112 and the body doped regions 118a/118b have different doping concentrations, the conventional method requires to fabricate a photomask and a photoresist layer, and the photoresist layer covers the termination area (i.e. first area 10) to prevent the doping concentration/profile of the bulk doped region 112 from being affected by the doping step of the body doped regions 118a/118b. However, with the method of the invention, the termination area (i.e. first area 10) has been covered by the single bulk isolation structure 104, so a blanket ion implantation process can be conducted to form P-type body doped regions 118a/118b without additional photomask and photoresist layer.

Afterwards, a doped region 120 of the first conductivity type is formed in the doped region 118b in the third area 30. The doped region 120 can be an N-type heavily doped region, serving as the source region of the device.

Referring to FIG. 1F, a dielectric layer 122 is formed on substrate 100 in the first, second and third areas 10, 20 and 30. The dielectric layer 122 has openings 124a and 124b therein. The opening 124a exposes a portion of the doped region 118a, and the opening 124b exposes a portion of the doped region 118b.

Thereafter, a blanket ion implantation process is preformed, so as to form doped regions 126a and 126b of the second conductivity type respectively in the doped regions 118a and 118b below the openings 124a and 124b. The doped regions 126a and 126b can be P-type heavily doped regions, for reducing the Ohmic resistance of the subsequently formed conductive plugs.

Afterwards, metal layers 128a and 128b are formed on the dielectric layer 122 respectively in the second and third areas 20 and 30. Each of the metal layers 128a and 128b extends onto a portion of the dielectric layer 122 in the first area 10. The metal layers 128a and 128b respectively fill in the openings 124a and 124b and therefore constitute conductive plugs 127a and 127b. The conductive plugs 127a and 127b are electrically connected to the doped regions 126a and 126b, respectively. In such manner, the seal ring structure in the second area 20 is short-circuited to the substrate 100. The semiconductor device of the present invention is thus completed.

The semiconductor device of the invention is illustrated with reference to FIG. 1F. In the semiconductor device of the invention, a substrate 100 has a first area 10, a second area 20 and a third area 30, and the second area 20 and the third area 30 are located beside the first area 10. An epitaxial layer 102 is disposed on the substrate 100. A single bulk isolation structure 104 is disposed on the epitaxial layer 102 in the first area 10. A bulk doped region 112 is disposed in the epitaxial layer 102 right below single bulk isolation structure 104. In an embodiment, the epitaxial layer 102 has a conductivity type the same with that of the substrate 100 but different from that of the bulk doped region 112. The doping depth of the bulk doped region 112 is gradually decreased toward the second area 20 while gradually increased toward the third area 30.

The said embodiment in which the first conductivity type is N-type and the second conductivity type is P-type is provided for illustration purposes, and is not construed as limiting the present invention. In another embodiment, the first conductivity type can be P-type and the second conductivity type can be N-type.

In summary, in the method of the invention, a photoresist layer serves as a VLD mask, and ions penetrate through a single bulk field oxide layer and into an epitaxial layer to create a VLD ion distribution. Since the opening sizes of the photoresist layer can be precisely defined, a wider process window can be provided for mass production. The method of the invention can easily control the VLD forming profile and therefore effectively improve the breakdown voltage. In the case of maintaining the same breakdown voltage, a smaller termination area and therefore a smaller device size can be easily obtained.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A termination structure, comprising:
a substrate of a first conductivity type;
an epitaxial layer of the first conductivity type, disposed on the substrate;
a single bulk isolation structure, disposed on the epitaxial layer; and
a bulk doped region of a second conductivity type, disposed in the epitaxial layer below the single bulk isolation structure, wherein a doping depth of the bulk doped region has a graded distribution.

2. The termination structure of claim 1, wherein the doping depth of the bulk doped region is gradually increased toward an active area.

3. The termination structure of claim 1, wherein the single bulk isolation structure has a thickness of about 100 angstroms to 10,000 angstroms.

4. The termination structure of claim 1, wherein the substrate comprises silicon, silicon carbide or gallium nitride.

5. The termination structure of claim 1, wherein the single bulk isolation structure is a field oxide layer.

6. The termination structure of claim 1, wherein the first conductivity type is N-type and the second conductivity type is P-type; or the first conductivity type is P-type and the second conductivity type is N-type.

7. A method of forming a termination structure, comprising:
forming an epitaxial layer of a first conductivity type on a substrate of the first conductivity type;
forming a single bulk isolation structure on the epitaxial layer;
forming a photoresist layer on the single bulk isolation structure, wherein the photoresist layer has a plurality of openings with different widths;
performing an ion implantation process by using the photoresist layer as a mask, so as to form a plurality of doped regions of a second conductivity type in the epitaxial layer below the single bulk isolation structure, wherein doping depths of the doped regions have a graded distribution.

8. The method of claim 7, wherein the doped regions are separate from each other, an i-th doped region is more away from the active area than an (i+1)-th doped region, a doping depth of the i-th doped region is less than a doping depth of the (i+1)-th doped region, and i is a positive integer.

9. The method of claim 8, further comprising performing an annealing process, so that the doped regions are connected to one another to form a bulk doped region.

10. The method of claim 7, wherein the ion implantation process has a doping energy of about 30 KeV to 1,000 KeV and a doping dose of about 1×10¹²/cm² to 100×10¹²/cm².

11. The method of claim 7, wherein the widths of the openings in the photoresist layer are gradually increased toward the active area.

12. The method of claim 7, wherein the single bulk isolation structure has a thickness of about 100 angstroms to 10,000 angstroms.

13. The method of claim 7, wherein the single bulk isolation structure is a field oxide layer.

14. The method of claim 7, wherein the first conductivity type is N-type and the second conductivity type is P-type; or the first conductivity type is P-type and the second conductivity type is N-type.

15. A semiconductor device, comprising:
a substrate of a first conductivity type, having a first area and a second area;
an epitaxial layer of the first conductivity type, disposed on the substrate;
a single bulk isolation structure, disposed on the epitaxial layer in the first area;
a bulk doped region of a second conductivity type, disposed in the epitaxial layer below the single bulk isolation structure, wherein a doping depth of the bulk doped region is gradually decreased toward the second area.

16. The semiconductor device of claim 15, wherein the single bulk isolation structure has a thickness of about 100 angstroms to 10,000 angstroms.

17. The semiconductor device of claim 15, wherein the substrate comprises silicon, silicon carbide or gallium nitride.

18. The semiconductor device of claim 15, wherein the single bulk isolation structure is a field oxide layer.

19. The semiconductor device of claim 15, wherein the substrate further comprises a third area, and the first area is located between the second area and the third area.

20. The semiconductor device of claim 19, wherein the first area is a termination area, the second area is a seal ring area, and the third area is an active area.
